(19) United States
(12) Patent Application Publication
(10) Pub. No.: US 2025/0336730 A1
(43) Pub. Date: Oct. 30, 2025

(54) PACKAGE GEOMETRIES TO ENABLE VISUAL INSPECTION OF SOLDER FILLETS

(71) Applicant: TEXAS INSTRUMENTS INCORPORATED, Dallas, TX (US)

(72) Inventors: LongTing LI, ChengDu City (CN); HuoYun DUAN, ChengDu City (CN)

(21) Appl. No.: 19/260,683

(22) Filed: Jul. 7, 2025

Related U.S. Application Data
(63) Continuation of application No. 17/491,405, filed on Sep. 30, 2021, now Pat. No. 12,354,918.

(51) Int. Cl. H01L 21/66; H01L 21/304; H01L 23/00; H05K 3/34

(52) U.S. Cl. CPC H01L 22/14; H01L 21/304; H01L 24/85; H01L 24/96; H01L 24/97; H05K 3/3405; H05K 3/3457; H01L 2224/85801; H01L 2224/85986; H05K 2203/162

(57) ABSTRACT

In examples, a method of manufacturing a semiconductor package comprises providing an array of unsingulated semiconductor packages, the array having a bottom surface and a conductive terminal exposed to the bottom surface, the conductive terminal including a slot configured to receive solder material. The method includes coupling a tape to the array of unsingulated semiconductor packages and applying a first saw blade to the bottom surface of the array to partially saw through a thickness of the array to a depth between two individual, adjacent, unsingulated semiconductor packages in the array of unsingulated semiconductor packages, the first saw blade producing a kerf. The method includes applying a second saw blade into the kerf to fully saw through the thickness of the array and produce a singulated semiconductor package, a width of the second saw blade narrower than the first saw blade. The conductive terminal is exposed to a side surface of the singulated semiconductor package, the side surface including a recessed area having a horizontal depth of no more than 30 microns.

This application is a continuation of patent application Ser. No. 17/491,405, filed Sep. 30, 2021, the contents of all of which are herein incorporated by reference in its entirety.

### BACKGROUND

Semiconductor chips are often housed inside semiconductor packages that protect the chips from deleterious environmental influences, such as heat, moisture, and debris. A packaged chip communicates with electronic devices outside the package via conductive terminals, such as leads, that are exposed to surfaces of the package. Within the package, the chip may be electrically coupled to the conductive terminals using any suitable technique. One such technique is the flip-chip technique, in which the semiconductor chip (also called a “die”) is flipped so the device side of the chip (in which circuitry is formed) is facing downward. The device side is coupled to the conductive terminals using, e.g., solder bumps. Another technique is the wirebonding technique, in which the device side of the semiconductor chip is oriented upward and is coupled to the conductive terminals using bond wires.

### SUMMARY

In examples, a method of manufacturing a semiconductor package comprises providing an array of unsingulated semiconductor packages, the array having a bottom surface and a conductive terminal exposed to the bottom surface, the conductive terminal including a slot configured to receive solder material. The method includes coupling a tape to the array of unsingulated semiconductor packages and applying a first saw blade to the bottom surface of the array to partially saw through a thickness of the array to a depth between two individual, adjacent, unsingulated semiconductor packages in the array of unsingulated semiconductor packages, the first saw blade producing a kerf. The method includes applying a second saw blade into the kerf to fully saw through the thickness of the array and produce a singulated semiconductor package, a width of the second saw blade narrower than the first saw blade. The conductive terminal is exposed to a side surface of the singulated semiconductor package, the side surface including a recessed area having a horizontal depth of no more than 30 microns.

### BRIEF DESCRIPTION OF THE DRAWINGS

For a detailed description of various examples, reference will now be made to the accompanying drawings in which:

FIG. 1 is a flow diagram of a method for forming semiconductor package side surface geometries that facilitate the visual inspection of solder fillets, in accordance with various examples.

FIGS. 2A-2D and FIGS. 3A-3H are process flows for forming semiconductor package side surface geometries that facilitate the visual inspection of solder fillets, in accordance with various examples.

FIGS. 4A-4C are perspective, profile, and top-down views of a semiconductor package coupled to a printed circuit board and having a side surface geometry that facilitates the visual inspection of solder fillets, in accordance with various examples.

FIG. 5 is a block diagram of an electronic device including a semiconductor package having a side surface geometry that facilitates the visual inspection of solder fillets, in accordance with various examples.

### DETAILED DESCRIPTION

In some types of semiconductor packages (e.g., quad flat no lead (QFN) packages), conductive terminals are exposed to, and are approximately flush with, the bottom and/or side surfaces of the package. Such semiconductor packages may be soldered to a printed circuit board (PCB) or other suitable component of an electronic device during a solder wetting process. Specifically, solder is heated to cause a reflow in which the solder melts and flows to form a secure connection with both the conductive terminals and with the PCB. In some cases, it is desirable for the solder wetting process to form a fillet extending beyond the vertical planes of the outer perimeter of a semiconductor chip package so the quality of the soldered connection may be visually verified from above (e.g., manually or via automatic visual inspection (AVI) techniques). Such verification is particularly common and useful in the automotive industry, for example.

Proper visual inspection of solder fillets from a top-down view calls for semiconductor package side surfaces that are flat or almost flat. Certain geometries of semiconductor package side surfaces may preclude proper visual inspection of solder fillets from a top-down view. For example, if the upper half of a semiconductor package side surface extends farther away from a center of the package than does the lower half of the side surface, the upper half of the side surface forms an overhang and the solder fillets may not be visible from above. Thus, quality control measures such as visual inspection are precluded.

Semiconductor package side surface geometries that preclude visual inspection are frequently formed due to the combination of jigsaw blade force during singulation and inadequate vacuum suction to hold the package stationary during singulation. These factors together cause movement of the semiconductor package during singulation, which results in an irregular semiconductor package side surface geometry. This irregular semiconductor package side surface geometry is often shaped in a way that precludes proper visual inspection of solder fillets, as described above. Furthermore, in conventional manufacturing processes, functional testing of the semiconductor packages is performed before the singulation process is fully complete, meaning that any sawing action performed after such functional testing may cause damage that negatively impacts package functionality but is not detected. Thus, defective packages are shipped to customers, diminishing both manufacturing yield and customer satisfaction.

This disclosure describes a semiconductor package singulation technique that mitigates the formation of aberrant semiconductor package side surface geometries that prevent the proper visual inspection of solder fillets. The singulation technique is applied to an array of semiconductor packages after removal from a mold chase in which mold compound is applied to an array of semiconductor dies and die pads, conductive terminals, bond wires, etc. that may be coupled to the semiconductor dies. The singulation technique is applied to the array of semiconductor packages to produce individual semiconductor packages that reliably have side surface geometries that facilitate visual inspection of solder fillets.

The singulation technique described herein entails a two-part sawing process. First, the singulation technique includes applying a tape to a top side of the array of semiconductor packages and sawing a bottom side of the array of semiconductor packages. Sawing the bottom side of the array of semiconductor packages includes sawing through some, but not all, of the thickness of the array of semiconductor packages. The singulation technique includes using water or another appropriate liquid (e.g., a solution) to remove burrs and debris that form from the first sawing instance. The singulation technique includes performing a second sawing instance in which a blade narrower than that used in the first sawing instance is used to saw through the remainder of the thickness of the array of semiconductor packages. Like the first sawing instance, the second sawing instance is performed on the bottom side of the array of semiconductor packages, and more specifically into a kerf that was formed by the first sawing instance. Singulation is then complete. A functional test of the semiconductor packages is performed after singulation is complete, thereby mitigating the risk of damage, diminished yield, and customer dissatisfaction caused by post-testing singulation. The packages may then be processed, packaged, and shipped to a customer.

When a semiconductor package singulated in accordance with examples described herein is coupled to a PCB using a solder wetting technique, the solder fillets will be easily visible from a top-down view, because the side surfaces of the semiconductor package do not have geometries that significantly obstruct the view of the solder fillets.

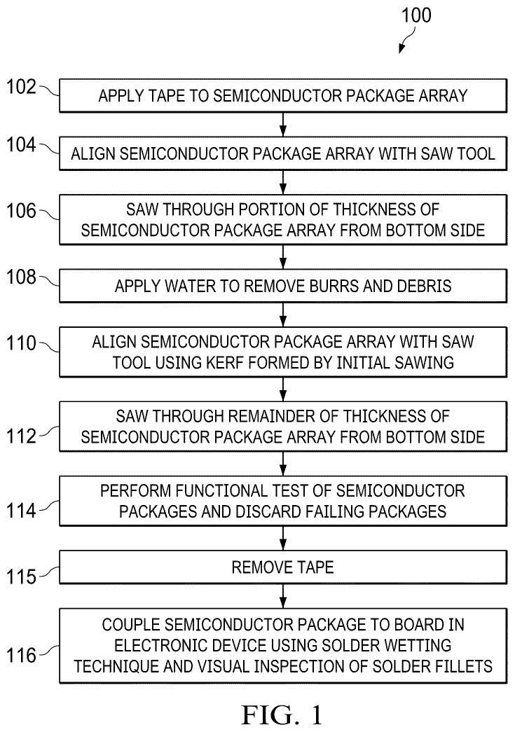

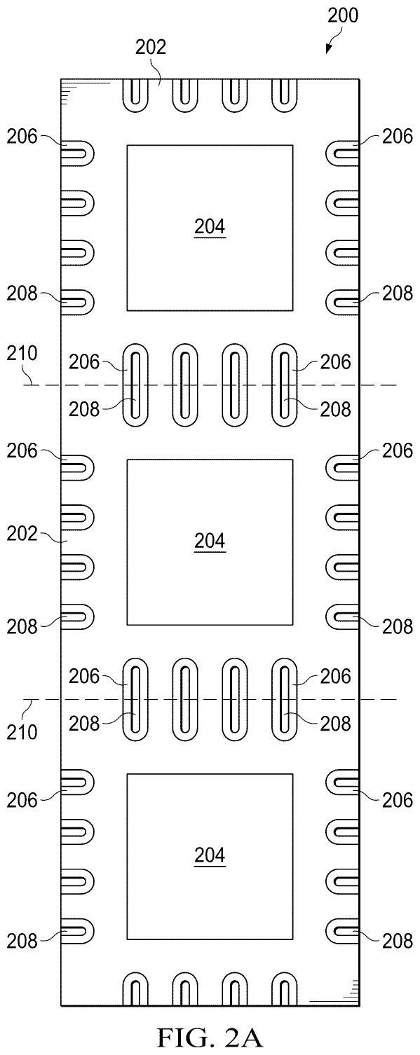

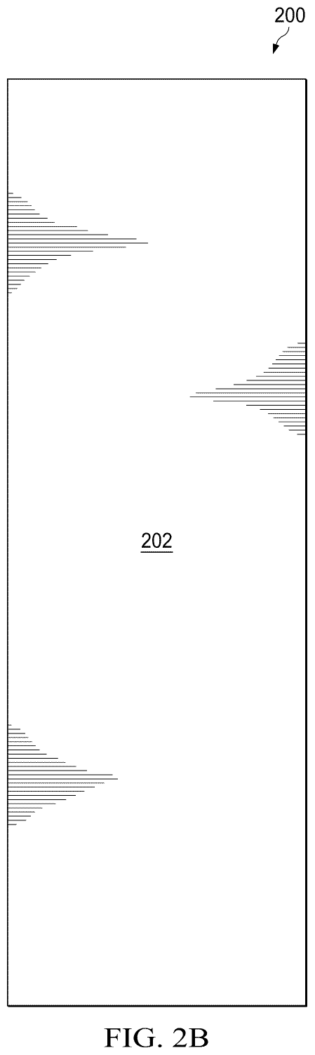

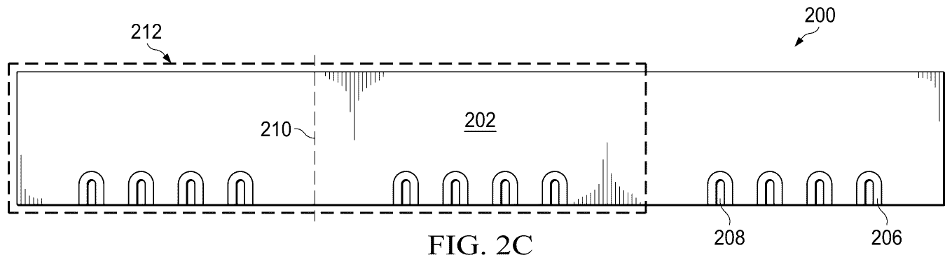

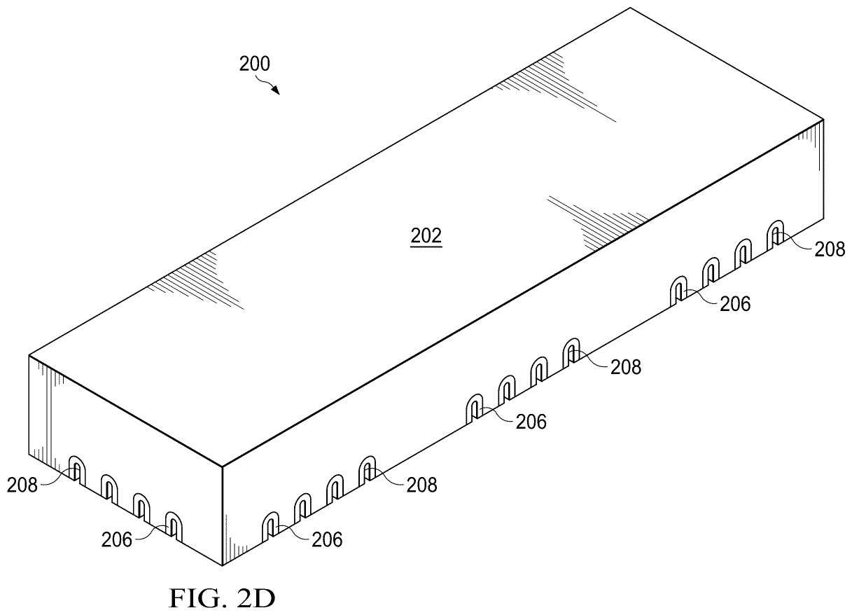

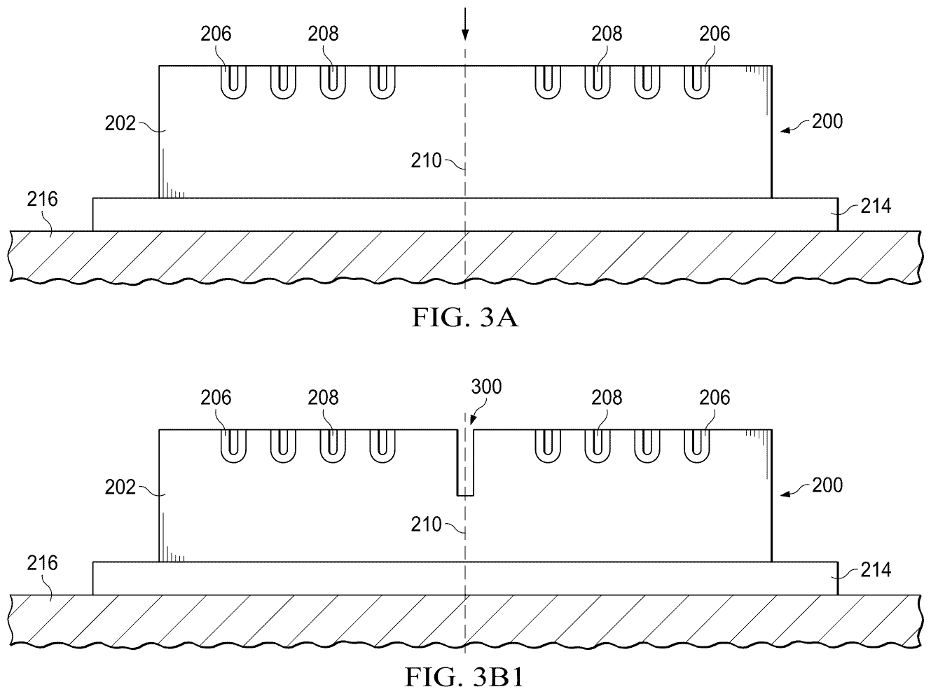

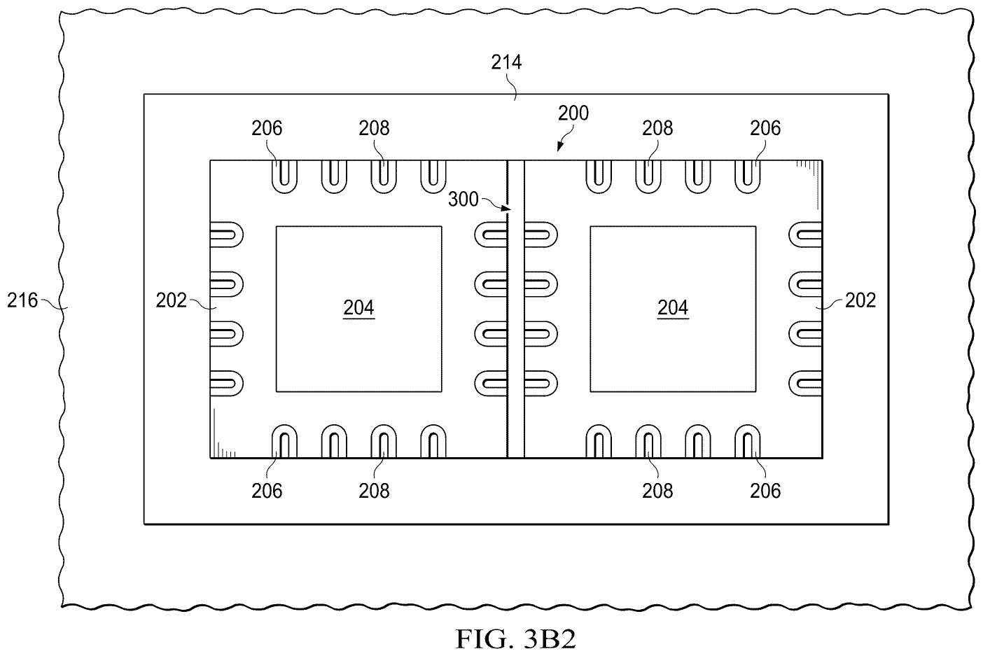

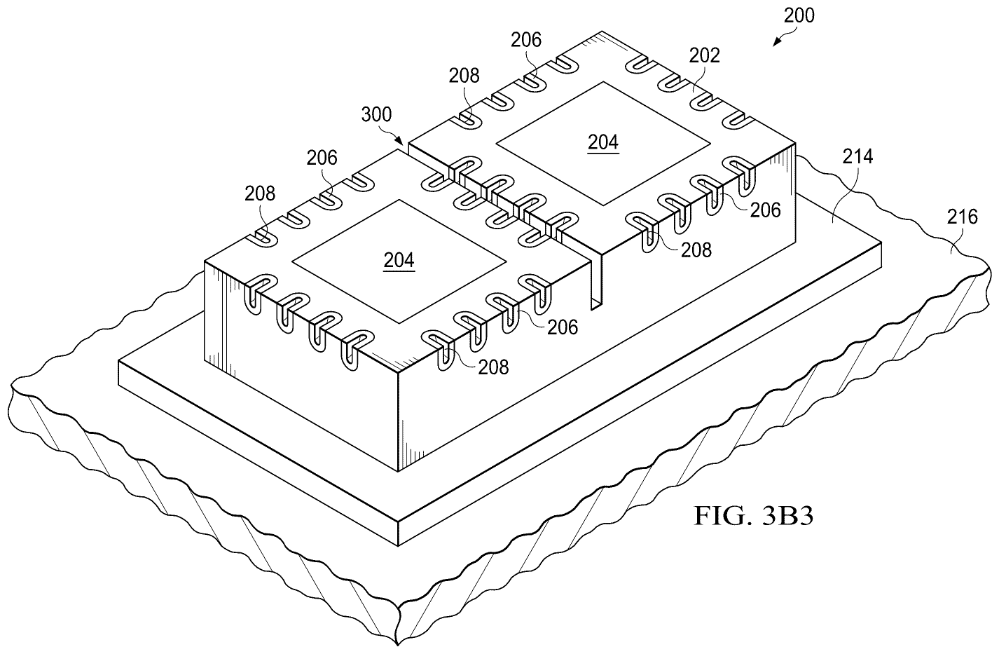

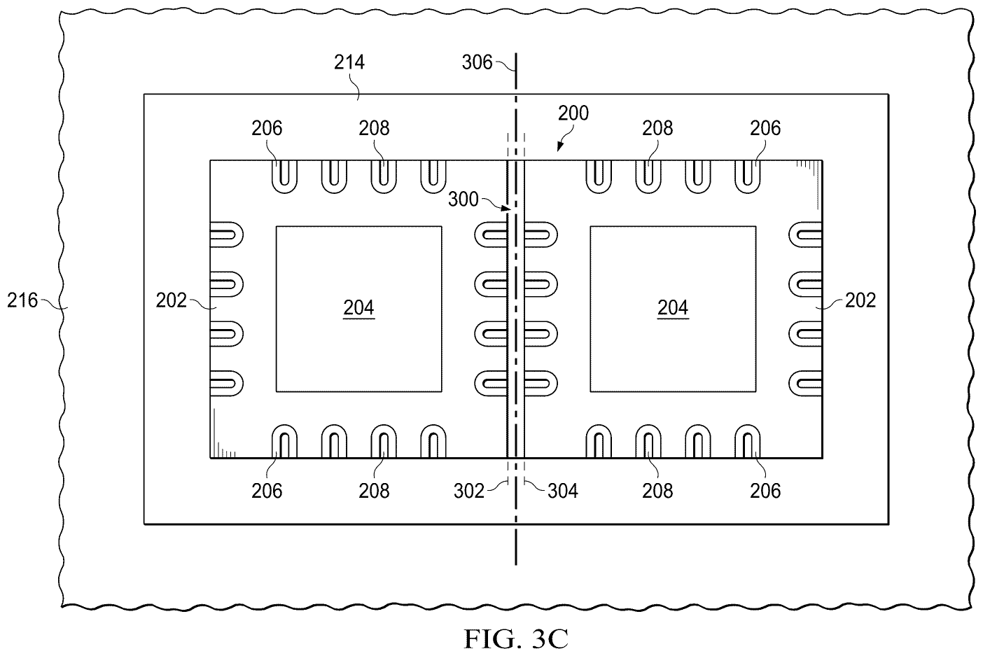

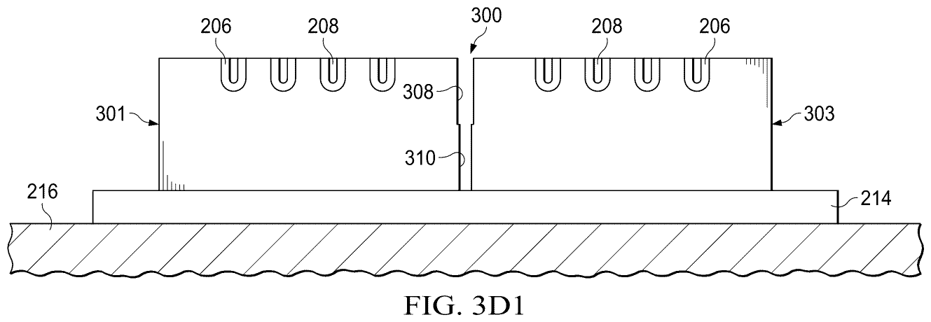

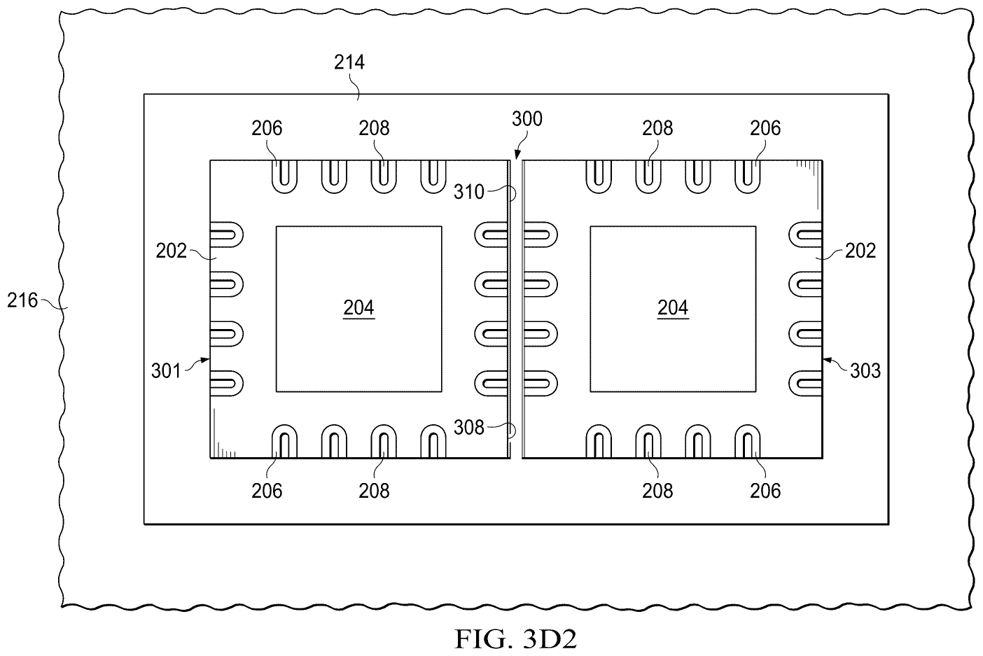

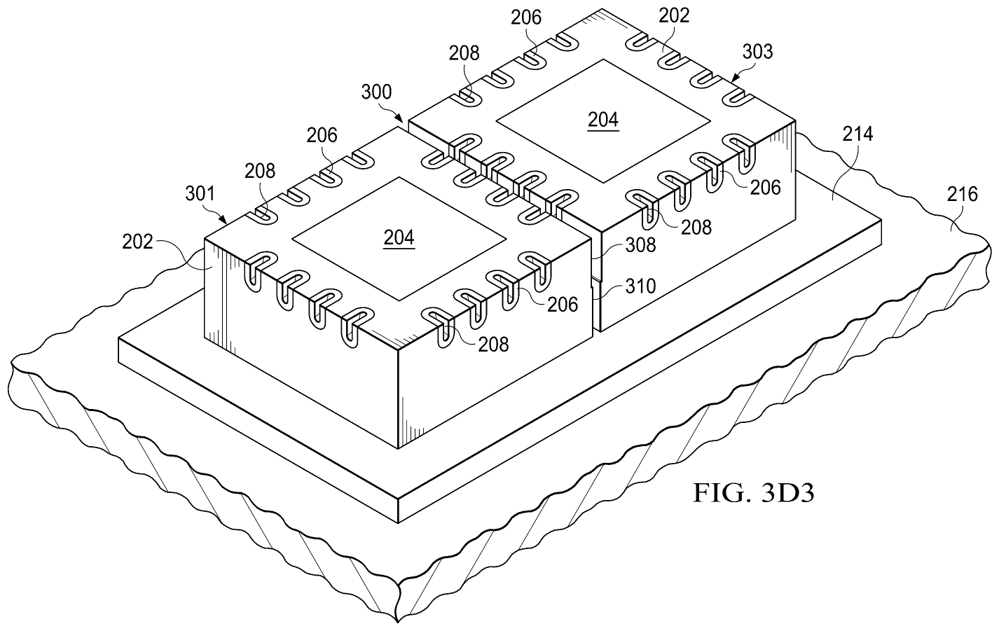

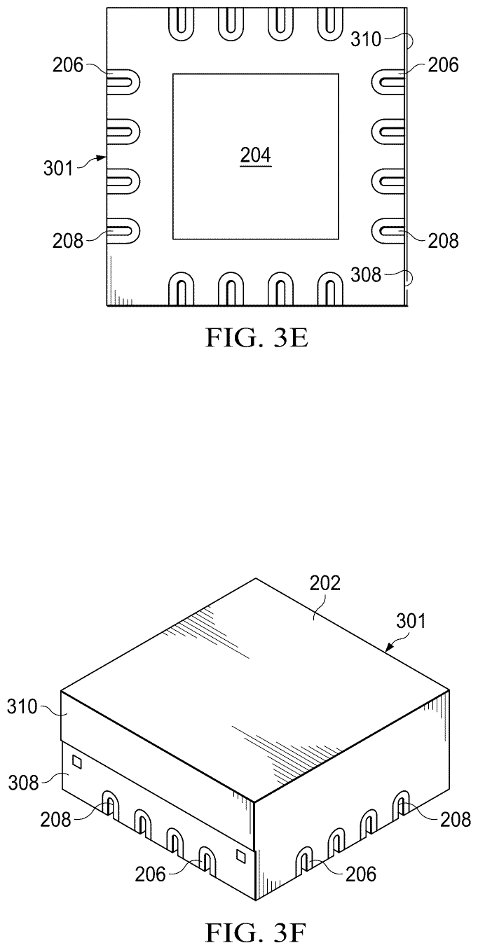

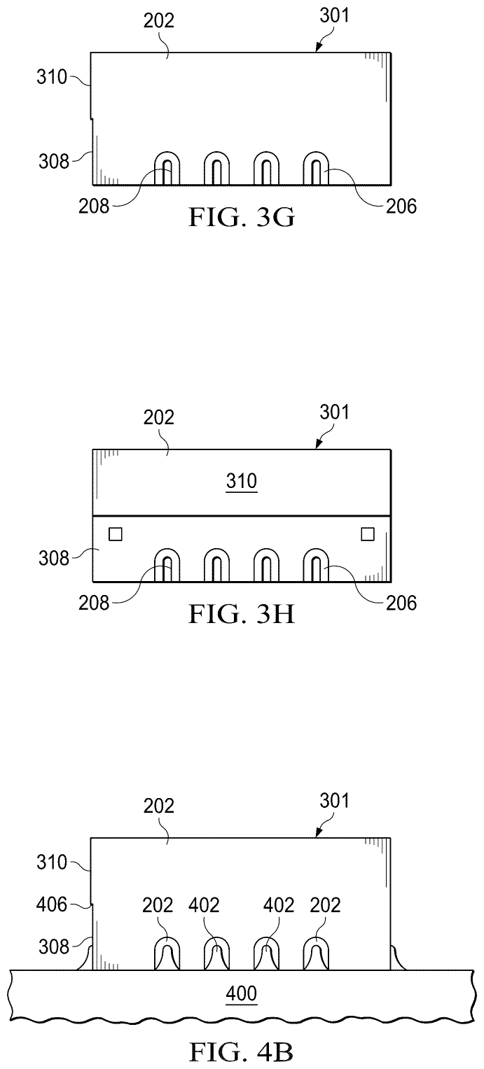

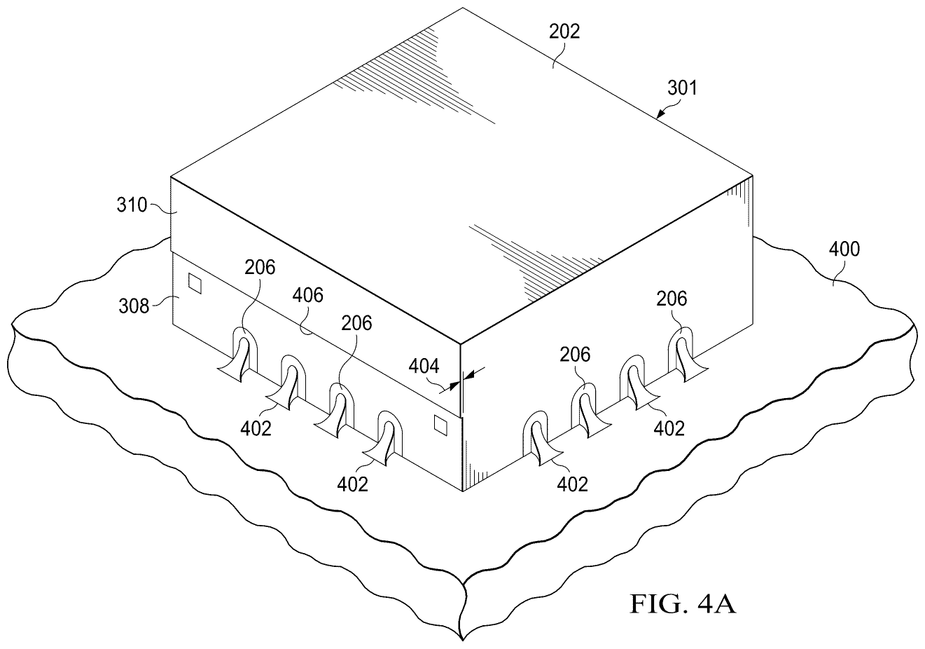

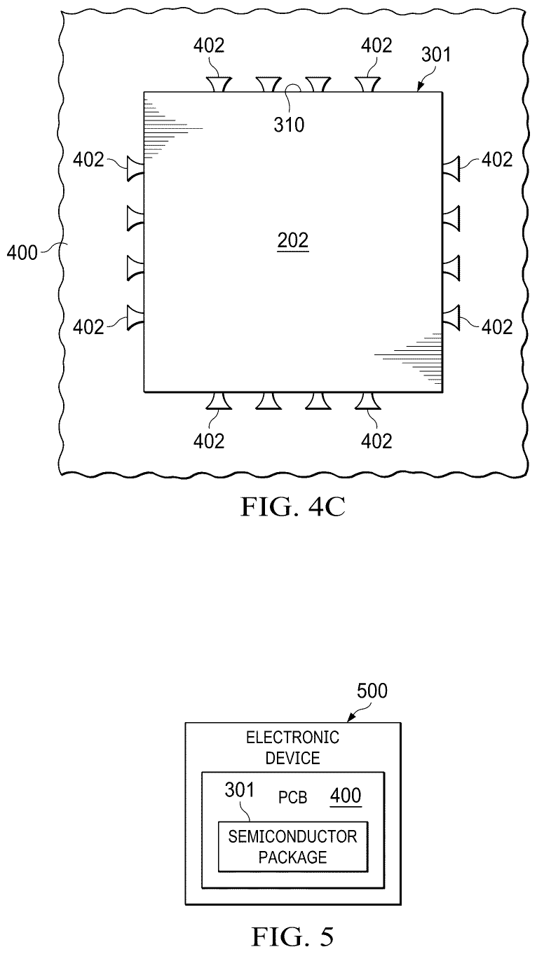

Example semiconductor package singulation techniques are now described with reference to the drawings. FIG. 1 is a flow diagram of a method 100 for forming semiconductor package side surface geometries that facilitate the visual inspection of solder fillets, in accordance with various examples. FIGS. 2A-2D and FIGS. 3A-3H are process flows for forming semiconductor package side surface geometries that facilitate the visual inspection of solder fillets, in accordance with various examples. FIGS. 4A-4C are perspective, profile, and top-down views of a semiconductor package coupled to a PCB and having a side surface geometry that facilitates the visual inspection of solder fillets, in accordance with various examples. Accordingly, FIGS. 1, 2A-2D, 3A-3H, and 4A-4C are now described in parallel.

The method 100 is applied to an array of unsingulated semiconductor packages. Thus, an example unsingulated semiconductor package array is first described with reference to FIGS. 2A-2D, followed by a description of the method 100 as applied to the example array. In an example unsingulated semiconductor package array, a set of semiconductor dies may be coupled to a lead frame strip, and appropriate wirebond connections, solder ball connections, etc. may be established between the semiconductor dies and their respective lead frames in the lead frame strip. The resulting assembly may then be positioned inside a mold chase. After a top member of the mold chase is closed, mold compound may be injected into the mold chase, thus covering the assembly of semiconductor dies on the lead frame strip with mold compound. The mold compound may be cured. The resulting structure is an array of unsingulated semiconductor packages that are coupled to each other by mold compound, tie bars, and dam bars.

FIG. 2A is a bottom-up view of an example unsingulated semiconductor package array 200, and FIG. 2B is a top-down view of the array 200. The bottom surface shown in FIG. 2A includes a mold compound 202, die pads 204 that are exposed to the bottom surface of the array 200, and conductive terminals 206 that are exposed to the bottom surface of the array 200. A bottom surface of an array of unsingulated semiconductor packages, as used herein, is the surface of the array of unsingulated semiconductor packages to which die pads and conductive terminals are exposed. The conductive terminals 206 include slots 208 configured to receive solder material, for example, during a solder wetting process. A dashed line 210 indicates an example location where the sawing processes of method 100 may be performed, as described in greater detail below. Similar sawing processes may be applied in other areas of the array 200. FIG. 2B depicts the top surface of the array 200, including the mold compound 202, where the tape of step 102 may be applied. FIG. 2C is a profile view of the array 200. The conductive terminals 206 and the slots 208 on the bottom surface (FIG. 2A) extend to the side surfaces of the array 200, as FIG. 2C shows. Numeral 212 indicates a representative portion of the array 200 that is used to describe the sawing processes of FIG. 1 below. FIG. 2D is a perspective view of the structure of FIGS. 2A-2C.

In step 102 of method 100, a tape, such as an ultraviolet (UV) tape, is applied to a top surface of the array 200, such as the top surface of the array 200 shown in FIG. 2C. FIG. 3A is a profile view of the array 200 coupled to a tape 214. The array 200 and the tape 214 may be positioned on a carrier, frame, or other suitable surface 216. In examples, the tape 214 has an adhesiveness ranging from 5.5 Newtons (N)/25 millimeters (mm) to 5.9 N/25 mm, with an adhesiveness less than this range being disadvantageous because it would result in movement of the structure during subsequent sawing, causing chipping and other structural defects, and with an adhesiveness greater than this range being disadvantageous because it can result in tape residue on packages that reduce manufacturing yield. In this way, the array 200 is held stationary during sawing processes. In step 104 of the method 100, the array 200 is aligned with a saw tool. In examples, the saw tool includes a saw blade useful to saw through some or all of the thickness of the array 200.

In step 106, the method 100 includes sawing through some, but not all, of the thickness of the array 200 from the bottom surface of the array 200 (e.g., the surface shown in FIG. 2A). FIG. 3B1 is a profile view of the array 200 after the sawing process of step 106 is complete. The array 200 includes a kerf 300 sawn along dashed line 210. A kerf, as used herein, is an opening formed in a material by sawing. In examples, the saw blade used to form the kerf 300 is a resin blade with an outlier diameter of 59 mm, a width of 0.27 mm, and a blade inner diameter of 40 mm. In examples, the saw blade is not a jigsaw blade because of the undesirable degree of force applied by the jigsaw blade and the resulting aberrant side surface geometries as described above. In examples, the saw blade has a width ranging from 0.26 mm to 0.28 mm, with a width below this range being disadvantageous because it can result in structural defects (e.g., burrs) during subsequent sawing, and with a width above this range being disadvantageous because it will result in an unacceptably large overhang unsuitable for quality control viewing (e.g., automatic visual inspection), for example, exceeding 30 microns. FIG. 3B2 is a top-down view of the array 200 having the kerf 300, and FIG. 3B3 is a perspective view of the array 200 having the kerf 300. The depth of the kerf 300 after the sawing of step 106 ranges from 50 percent of the thickness of the array 200 to 60 percent of the thickness of the array 200, with a depth greater than this range being disadvantageous because the remaining thickness of the array 200 would not be able to withstand the application of pressurized fluid for burr removal, and with a depth less than this range being disadvantageous because it would result in the formation of undesirable structural features during a second sawing that would preclude adequate visual inspection for quality control measures.

In step 108, the method 100 includes applying a liquid to the array 200 to remove burrs and debris. In some examples, water may be applied. In some examples, deionized water may be applied at very high pressure in the range of 60 mega pascals (MPa) to 80 MPa. Other appropriate liquids or solutions may be used, and in some examples, other techniques (e.g., vacuum techniques) may be useful to remove burrs and debris.

In step 110, the method 100 includes re-aligning the array 200 with the saw tool using the kerf 300. FIG. 3C is a top-down view of the structure of FIGS. 3B1-3B3. An example saw tool may include peripheral alignment lines 302, 304 and a central alignment line 306, for example on a display panel, a viewer, a lens, etc. The edges of the kerf 300 (e.g., the edges of the bottom surface of array 200 abutting the kerf 300) may be aligned with the peripheral alignment lines 302, 304, as shown in FIG. 3C. The central alignment line 306 may be aligned with the kerf 300 (e.g., the gap between the edges of the kerf 300), as shown. This re-alignment in step 110 promotes a more accurate sawing process in step 112, in which the saw tool is used to apply a different saw blade than that used in step 106 into the kerf 300 via the bottom surface of the array 200 to fully saw through the array 200. In examples, the saw blade used in step 112 is narrower than the saw blade used in step 106. In examples, the width of the saw blade used in step 112 has a range from 0.255 mm to 0.265 mm, with a blade width above this range being disadvantageous because it will cause the formation of undesirable structural features such as burrs, and with a blade width below this range being disadvantageous because it will result in other undesirable structural features, such as undesirably large overhangs exceeding 30 microns that preclude adequate visual inspection for quality control purposes. In examples, the difference in width between the saw blade used in step 106 and the saw blade used in step 112 (with the saw blade used in step 112 being narrower) is within a range from 0 microns to 25 microns, with a difference smaller than this range being disadvantageous because it will result in the formation of undesirable structural features such as burrs, and with a difference greater than this range being disadvantageous because it will result in other undesirable structural features, such as undesirably large overhangs exceeding 30 microns. In examples, the saw blade used in step 112 is a resin blade. In examples, the saw blade used in step 112 is not a jigsaw blade because of the undesirable degree of force applied by the jigsaw blade and the resulting aberrant side surface geometries as described above.

FIG. 3D1 is a profile view depicting the array 200 after complete singulation in step 112. As shown, the kerf 300 extends through the entire thickness of the formerly unsingulated array 200, thus producing a singulated semiconductor package 301 and a singulated semiconductor package 303. A side surface geometry of the singulated semiconductor package 301 includes a recessed area 308 and a non-recessed area 310. The horizontal depth of the recessed area 308 relative to the non-recessed area 310 is no more than 30 microns. This horizontal depth may be controlled by the difference in saw widths used in steps 106 and 112. A larger difference in saw widths used in steps 106 and 112 results in a greater horizontal depth of the recessed area 308, while a smaller difference in saw widths used in steps 106 and 112 results in a lesser horizontal depth of the recessed area 308. FIG. 3D2 is a top-down view of the structure of FIG. 3D1, and FIG. 3D3 is a perspective view of the structure of FIG. 3D1. FIG. 3E is a bottom-up view of the singulated semiconductor package 301. FIG. 3F is a perspective view of the singulated semiconductor package 301. FIG. 3G is a profile view of the singulated semiconductor package 301, and FIG. 3H is another profile view of the singulated semiconductor package 301.

In step 114, the method 100 includes performing a functional test of the singulated semiconductor package 301 and discarding any failing packages. For example, the functional test may include applying specific signals to specific conductive terminals 206 of the singulated semiconductor package 301 and measuring output signals provided on other conductive terminals 206 of the singulated semiconductor package 301 to determine whether a defect is present in bond wires, bond pads, or the semiconductor die within the singulated semiconductor package 301. A failing package 301 may be discarded or repaired. Tape may be removed in step 115.

In step 116, the method 100 includes coupling the singulated semiconductor package 301 to a PCB to be included in an electronic device using a solder wetting technique and performing a visual inspection (e.g., AVI) of the resulting solder fillets. FIG. 4A is a perspective view of the singulated semiconductor package 301 coupled to a PCB 400. Solder fillets 402 couple conductive terminals 206 to the PCB 400 (e.g., to bond pads on the PCB 400). The solder fillets 402 are formed in part when solder material rises to fill the slots 208. The recessed area 308 is offset from the non-recessed area 310 by a horizontal depth 404 that does not exceed 30 microns. Because the horizontal depth 404 does not exceed 30 microns, the solder fillets 402 are adequately visible from a top-down view to perform visual inspections (e.g., AVI). In addition, a step 406 at an interface between the recessed area 308 and the non-recessed area 310 is substantially flat and is substantially parallel to the top and bottom surfaces of the singulated semiconductor package 301, as shown in FIG. 4A. FIG. 4B is a profile view of the structure of FIG. 4A, and FIG. 4C is a top-down view of the structure of FIG. 4A.

Experimental data supports the efficacy of the techniques described herein, including the critical parameter ranges described herein, in consistently producing horizontal depths 404 that are below 30 microns. In an experiment involving horizontal depth measurements across a variety of package sizes, the average maximum horizontal depth measurement of recessed areas measured 17.46 microns. No recessed area depth measurement exceeded 21.3 microns. All but one of the packages tested produced maximum recessed area depth measurements less than 20 microns. The average recessed area depth measurement across all packages tested did not exceed 6.48 microns. The average depth measurement for each tested package, when ordered, produced a median of 5.79 microns. The smallest process capability index (CPK) value calculated for any package tested was 1.78, indicating excellent ability to meet recessed area depth specifications, and the largest CPK value calculated for any package tested was 2.49, indicating superior ability to meet recessed area depth specifications. Thus, this experimental data establishes the efficacy of the techniques described herein, including the critical parameter ranges described herein, in producing singulated semiconductor packages having sufficiently small side surface recessed area depth measurements to permit AVI of conductive terminal solder fillets.

FIG. 5 is a block diagram of an electronic device 500 including a semiconductor package having a side surface geometry that facilitates the visual inspection of solder fillets, in accordance with various examples. For example, the electronic device 500 may be a laptop, desktop, or notebook computer, a smartphone, an appliance, a vehicle, etc. The electronic device 500 includes a PCB 400 and the singulated semiconductor package 301 coupled to the PCB 400. The singulated semiconductor package 301 has the side surface geometries described above and, thus, when it is coupled to the PCB 400, visual inspection techniques (e.g., AVI) are possible to ensure that proper solder fillets are formed.

The term “couple” is used throughout the specification. The term may cover connections, communications, or signal paths that enable a functional relationship consistent with this description. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A. Unless otherwise stated, “about,” “approximately,” or “substantially” preceding a value means+/−10 percent of the stated value. Modifications are possible in the described examples, and other examples are possible within the scope of the claims.

What is claimed is:

1. A semiconductor package, comprising:
a top surface;
a bottom surface;
a side surface; and
a conductive terminal on the bottom surface and on the side surface, wherein the side surface comprises a first portion with a first thickness and a recessed portion with a second thickness, the conductive terminal is on the recessed portion, and the first thickness is smaller than the second thickness.

2. The semiconductor package of claim 1, wherein the semiconductor package is a qual flat no lead (QFN) package.

3. The semiconductor package of claim 1, further comprising a semiconductor die coupled to the conductive terminal via a bond wire.

4. The semiconductor package of claim 3, further comprising a mold compound covering the semiconductor die, the bond wire, and portions of the conductive terminal.

5. The semiconductor package of claim 1, further comprising a die pad on the bottom surface.

6. The semiconductor package of claim 1, wherein the side surface further comprises a step between the first portion and the recessed portion, and a width of the step is no more than 30 microns.

7. The semiconductor package of claim 6, wherein the step is substantially parallel with the top surface.

8. An electronic device, comprising:
a printed circuit board (PCB); and
a semiconductor package attached to the PCB, the semiconductor package comprising a top surface, a bottom surface, a side surface, and a conductive terminal on the bottom surface and on the side surface, wherein the side surface comprises a first portion with a first thickness and a recessed portion with a second thickness, the conductive terminal is on the recessed portion, and the first thickness is smaller than the second thickness.

9. The electronic device of claim 8, wherein the semiconductor package is a qual flat no lead (QFN) package.

10. The electronic device of claim 8, wherein the semiconductor package further comprises a semiconductor die coupled to the conductive terminal via a bond wire.

11. The electronic device of claim 10, wherein the semiconductor package further comprises a mold compound covering the semiconductor die, the bond wire, and portions of the conductive terminal.

12. The electronic device of claim 8, wherein the semiconductor package further comprises a die pad on the bottom surface.

13. The electronic device of claim 8, wherein the side surface further comprises a step between the first portion and the recessed portion, and a width of the step is no more than 30 microns.

14. The electronic device of claim 13, wherein the step is substantially parallel with the top surface.

15. The electronic device of claim 8, wherein the semiconductor package is attached to the PCB via a solder material.
